(19) United States
(12) Patent Application Publication
(10) Pub. No.: US 2025/0212548 A1
(43) Pub. Date: Jun. 26, 2025

(54) SYSTEMS, APPARATUSES, AND METHODS, FOR SCALABLE FABRICATION OF PHOTONIC DEVICES

(71) Applicant: Quantinuum LLC, Broomfield, CO (US)

(72) Inventors: Adam Jay Ollanik, Boulder, CO (US); Rezlind Bushati, Broomfield, CO (US); Matthew Blain, Broomfield, CO (US); Susan Eileen Shore, Golden Valley, MN (US); Amit Agrawal, Gaithersburg, MD (US); Henri Lezec, Gaithersburg, MD (US); Wenqi Zhu, Gaithersburg, MD (US); Chris Langer, Highlands Ranch, CO (US); Daniel Ouellette, Minneapolis, MN (US)

(21) Appl. No.: 18/988,622

(22) Filed: Dec. 19, 2024

Related U.S. Application Data
(60) Provisional application No. 63/613,357, filed on Dec. 21, 2023.

(51) Int. Cl. H10F 71/00; H10N 50/01

(52) U.S. Cl. CPC H10F 71/127; H10N 50/01

(57) ABSTRACT

Embodiments of the disclosure provide apparatuses, systems, and methods related to photonic devices. A method for fabricating photonic devices may include forming a mask layer on a surface of a mold layer. The mask layer may define one or more openings that expose one or more select portions of a surface of the mold layer. The method may include etching through the one or more openings to form one or more cavities within the mold layer and depositing photonic material within the one or more cavities. Depositing the photonic material may include overfilling the one or more cavities to form an over-filled layer on the mask layer. The method may include removing the over-filled layer and the hard mask layer.

### CROSS-REFERENCE TO RELATED APPLICATIONS

This application claims priority to U.S. Provisional Patent Application 63/613,357 filed on Dec. 21, 2023, which is incorporated herein by reference in its entirety.

### STATEMENT REGARDING FEDERALLY SPONSORED RESEARCH

This invention was made with United States Government support from the National Institute of Standards and Technology (NIST), an agency of the United States Department of Commerce, under Collaborative Research and Development Agreement CN-21-0096. The Government has certain rights in this invention.

### TECHNICAL FIELD

Various embodiments relate to apparatuses, systems, and methods, relating to photonic devices. An example embodiment relates to fabrication of photonic devices.

### BACKGROUND

In several contexts, photonic structures (e.g., metasurfaces) are integrated into devices and systems to provide various capabilities. Applicant has discovered problems associated with fabrication of photonic devices. Through applied effort, ingenuity, and innovation, Applicant has solved many of the identified problems by developing the embodiments of the present disclosure, many examples of which are described in detail below.

### BRIEF SUMMARY

In general, embodiments of the present disclosure herein related to photonic devices comprising one or more photonic structures. In accordance with one aspect of the present disclosure, an example method of fabricating a photonic device comprises forming a mask layer on a surface of a mold layer, the mask layer defining one or more openings, wherein the one or more openings expose one or more select portions of the surface of the mold layer; etching through the one or more openings to form one or more cavities within the mold layer; depositing photonic material within the one or more cavities, wherein depositing the photonic material comprises overfilling the one or more cavities to form an over-filled layer on the mask layer; and removing the over-filled layer and the mask layer.

In some example embodiments, the example method further comprises polishing the mold layer before forming the mask layer.

In some example embodiments, depositing the photonic material comprises performing atomic layer deposition to fill the one or more cavities with the photonic material.

In some example embodiments, depositing the photonic material comprises performing chemical vapor deposition to fill the one or more cavities with the photonic material.

In some example embodiments, the example method further comprises removing the mold layer.

In some example embodiments, the mold layer is formed from material suitable for cladding and comprises a first cladding layer.

In some example embodiments, the example method further comprises depositing a top cladding layer on the first cladding layer.

In some example embodiments, forming the mask layer on the mold layer comprises forming a patterned resist layer on the mold layer, the patterned resist layer comprising one or more resist structures positioned on the one or more select portions of the surface of the mold layer; depositing a hard mask layer on the mold layer; and removing the one or more resist structures to define the one or more openings.

In some example embodiments, the one or more resist structures comprises a plurality of resist structures that are spaced apart and distributed across the mold layer, and the hard mask layer has a thickness that is less than the thickness of each of the one or more resist structures.

In some example embodiments, the mask layer comprises an etched hard mask layer or a polymer-based etch mask.

In some example embodiments, each of the one or more cavities has a salient profile.

In accordance with another aspect of the present disclosure, an example method of fabricating a photonic device comprises forming a mask layer on a surface of a mold layer, the mask layer defining one or more openings, wherein the one or more openings expose one or more select portions of the surface of the mold layer; etching through the one or more openings to form one or more cavities within the mold layer; performing an oxidizing operation on the mold layer to form a first cladding layer; depositing photonic material within the one or more cavities; wherein depositing the photonic material comprises overfilling the one or more cavities to form an over-filled layer on the mask layer; and removing the over-filled layer.

In some example embodiments, the example method further comprises polishing the mold layer before forming the mask layer.

In some example embodiments, depositing the photonic material comprises performing atomic layer deposition to fill the one or more cavities with the photonic material.

In some example embodiments, depositing the photonic material comprises performing chemical vapor deposition to fill the one or more cavities with the photonic material.

In some example embodiments, the example method further comprises removing the mask layer.

In some example embodiments, the example method further comprises depositing a top cladding layer on the first cladding layer.

In some example embodiments, forming the mask layer on the mold layer comprises forming a patterned resist layer on the mold layer, the patterned resist layer comprising one or more resist structures positioned on the one or more select portions of the surface of the mold layer; depositing a hard mask layer on the mold layer; and removing the one or more resist structures to define the one or more openings.

In some example embodiments, the one or more resist structures comprises a plurality of resist structures that are spaced apart and distributed across the mold layer, and the hard mask layer has a thickness that is less than the thickness of each of the one or more resist structures.

In some example embodiments, each of the one or more cavities has a salient profile.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 is a schematic diagram illustrating an example quantum computing system comprising an atomic object confinement apparatus comprising photonic structures, according to an example embodiment.

FIG. 2 provides a flowchart illustrating various processes, procedures, and/or operations for scalable fabrication of photonic devices in accordance with one example embodiment.

FIGS. 3A-3J provide cross section views of various stages of fabricating photonic devices in accordance with an example embodiment.

FIG. 4 provides a flowchart illustrating various processes, procedures, and/or operations for scalable fabrication of photonic devices in accordance with another example embodiment.

FIGS. 5A-5K provide cross section views of various stages of fabricating photonic devices in accordance with another example embodiment.

FIG. 6 provides a schematic diagram of an example controller of a quantum computer that may be used in accordance with an example embodiment.

FIG. 7 provides a schematic diagram of an example computing entity of a quantum computer system that may be used in accordance with an example embodiment.

### DETAILED DESCRIPTION

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within engineering and/or manufacturing limits and/or within user measurement capabilities, unless otherwise indicated. Like numbers refer to like elements throughout.

In some examples, a photonic device (e.g., planar photonic devices, nano photonic devices, micro-photonic devices, and/or the like) may include photonic structures (e.g., metasurfaces) that describe material with sub-wavelength thickness. In some examples, photonic structures (also referred to interchangeably herein as metasurfaces) may comprise an array of nanostructures (e.g., an array of nanostructures films). In some examples, the photonic structures comprise diffractive optical elements. In various embodiments, a photonic device may be fabricated using a damascene fabrication process configured for robustness, repeatability, scalability, and compatibility with foundry processes. For example, embodiments of the present disclosure leverage a specially configured single damascene fabrication process and/or a double damascene fabrication process to provide a scalable fabrication that is robust, repeatable, and compatible with foundry processes.

Embodiments of the present disclosure provide for fabrication of photonic devices that may be utilized in various applications, including, for example, quantum processing applications, UV/VIS nanophotonics applications, and/or the like. For example, a signal management system associated with and/or comprising an atomic object confinement apparatus may comprise one or more manipulation elements. The one or more manipulation elements may be used to provide manipulation signals to atomic object positions defined by the atomic object confinement apparatus and/or collect, capture, detect, and/or measure emitted signal emitted by atomic objects located at atomic object positions. The atomic object, for example, may be an atom and/or ion. In some examples, the atomic object may be qubit atomic object of an atomic object crystal comprising two or more atomic objects. In some examples, the atomic object confinement apparatus is an ion trap (e.g., a surface ion trap, Paul trap, and/or the like).

In various embodiments, the one or more signal manipulation elements are metamaterial arrays, and each metamaterial array comprises a plurality of metamaterial structures (e.g., photonic structures) which each define and/or comprise a respective metamaterial surface. In some embodiments, the array of metamaterials structures (e.g., the composite surface formed by combining the respective metamaterial surfaces for the plurality of metamaterial structures) forms and/or provides a photonic metasurface. A photonic metasurface may describe an engineered surface designed to manipulate light through coherent interference implemented through lock control of the amplitude, phase, and/or polarization of reflected or transmitted light. This control is implemented by an array of optical scattering elements (e.g., the metamaterial structures), each of which have dimensions on the scale of the wavelength of light or smaller in at least one dimension, with spacing of the scale of the wavelength of light or smaller. For example, a photonic metasurface, as used herein, refers to the composite metasurface formed by the plurality of metamaterial structures (e.g., photonic structures) of a metamaterial array. The metamaterial structures of a metamaterial array are approximately wavelength or sub-wavelength (e.g., nanometer scale), high contrast structures (compared to other portions of the surface of the atomic object confinement apparatus) whose geometry, size, arrangement, and orientation control the phase, amplitude, and polarization of electromagnetic waves.

In some examples, at least one of the signal manipulation elements (e.g., comprising photonic structures) of the signal management system is disposed on a surface of the atomic object confinement apparatus and/or at least partially within a substrate on which the atomic object confinement apparatus is formed. For example, the atomic object confinement apparatus is formed on a substrate, in various examples, with the at least one signal manipulation element formed and/or disposed on a surface of the substrate. The first substrate may comprise multiple layers of circuitry configured to control various elements/components of the operation of the functioning of the atomic object confinement apparatus. In an example embodiment, at least one of the signal manipulation elements is part of the atomic object confinement apparatus and set back and/or recessed with respect to the surface of the atomic object confinement apparatus. For example, at least one signal manipulation element may be located at a fabricated layer that is within the substrate and/or not directly on the surface defined by the plane of the atomic object confinement apparatus in some examples. For example, there may be a hole or opening in the surface of the atomic object confinement apparatus with the at least one signal manipulation element recessed therein. In an example, embodiment, a layer encloses the at least one signal manipulation element within the hole or opening. Various embodiments provide an atomic object confinement apparatus having one or more signal manipulation elements formed and/or disposed on the surface of the atomic object confinement apparatus and/or as part of the substrate comprising the atomic object confinement apparatus.

It should be understood that, in some examples, a photonic structure may be disposed within an interior layer of a programmable interface controller (PIC), an integrated device, and/or the like. In some examples, a photonic structure may be formed on the surface of a substrate. For example, a photonic structure may occupy the outer face of a substrate in some examples.

### Example Quantum Computing System Comprising an Atomic Object Confinement Apparatus

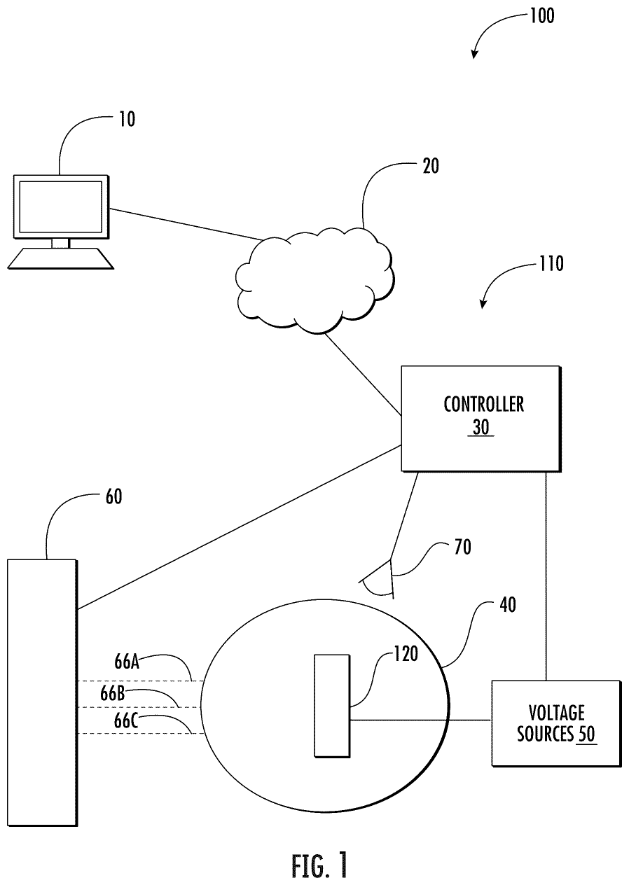

FIG. 1 provides a schematic diagram of an example quantum computing system 100 comprising an atomic object confinement apparatus 120 (e.g., an ion trap and/or the like), in accordance with an example embodiment. In various embodiments, a plurality of signal manipulation elements is formed and/or disposed on a surface of the atomic object confinement apparatus 120. In various embodiments, at least a portion of the signal manipulation elements formed and/or disposed on the surface of the atomic object confinement apparatus 120 are configured to be induced to emit an action signal toward and/or focused onto a respective atomic object position responsive to an incoming signal being incident thereon. The incoming signal may be at least a portion of a manipulation signal generated by the manipulation source of the quantum computer 110.

In various embodiments, the quantum computing system 100 comprises a computing entity 10 and a quantum computer 110. In various embodiments, the quantum computer 110 comprises a controller 30, a cryogenic and/or vacuum chamber 40 enclosing a confinement apparatus 120 (e.g., an ion trap). In various embodiments, the cryogenic and/or vacuum chamber 40 is a temperature and/or pressure-controlled chamber. For example, the quantum computing system 100 may comprise vacuum and/or temperature control components that are operatively coupled to the cryogenic and/or vacuum chamber 40.

In an example embodiment, the manipulation signals generated by the manipulation sources 60 are provided to the interior of the cryogenic and/or vacuum chamber 40 (e.g., where the atomic object confinement apparatus 120 is located via corresponding optical paths (e.g., 66A, 66B, 66C). In various embodiments, the optical paths are defined at least in part by one or more components and/or elements of the signal management system.

In an example embodiment, the one or more manipulation sources 60 may comprise one or more lasers (e.g., optical lasers, microwave sources, and/or the like). In various embodiments, each manipulation source is configured to generate a manipulation signal having a respective characteristic wavelength in the microwave, infrared, visible, or ultraviolet portion of the electromagnetic spectrum. In various embodiments, the one or more manipulation sources 60 are configured to manipulate and/or cause a controlled quantum state evolution of the one or more atomic objects within the confinement apparatus 120. For example, in an example embodiment, wherein the one or more manipulation sources 60 comprise one or more lasers, the lasers may provide one or more laser beams to atomic objects trapped by the confinement apparatus 120 within the cryogenic and/or vacuum chamber 40.

For example, a manipulation source 60 generates a manipulation signal that is provided as an incoming signal to an appropriate signal manipulation element of the signal management system. The incoming signal being incident on the signal manipulation element, for example a metamaterial array, induces the plurality of metamaterial structures of the metamaterial array to emit an action signal directed toward and/or focused at a corresponding atomic object position of the atomic object confinement apparatus. For example, the manipulation sources 60 may be configured to generate one or more beams that may be used to initialize an atomic object into a state of a qubit space such that the atomic object may be used as a qubit of the confined atomic object quantum computer, perform one or more gates on one or more qubits of the confined atomic object quantum computer, read and/or determine a state of one or more qubits of the confined atomic object quantum computer, and/or the like.

In various embodiments, the quantum computer 110 comprise an optics collection system 70 configured to collect and/or detect photons generated by qubits (e.g., during reading procedures). The optics collection system 70 may comprise one or more optical elements (e.g., lenses, mirrors, waveguides, fiber optics cables, and/or the like) and one or more photodetectors. In various embodiments, the photodetectors may be photodiodes, photomultipliers, charge-coupled device (CCD) sensors, complementary metal oxide semiconductor (CMOS) sensors, Micro-Electro-Mechanical Systems (MEMS) sensors, and/or other photodetectors that are sensitive to light at an expected fluorescence wavelength of the qubits of the quantum computer. In various embodiments, the detectors may be in electronic communication with the controller 30 via one or more A/D converters and/or the like. For example, an atomic object being read and/or having its quantum state determined may emit an emitted signal, at least a portion of which is incident on a collection array of the signal management system. The emitted signal being incident on the collection array induces the plurality of metamaterial structures of the collection array to emit a detecting signal directed toward and/or focused at collection optics of the atomic object confinement apparatus. The collection optics are configured to provide the collection signal to a photodetector.

In various embodiments, the quantum computer 110 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding electrode elements (e.g., electrodes) of the confinement apparatus, in an example embodiment.

In various embodiments, a computing entity 10 is configured to allow a user to provide input to the quantum computer 110 (e.g., via a user interface of the computing entity 10) and receive, view, and/or the like output from the quantum computer 110. The computing entity 10 may be in communication with the controller 30 of the quantum computer 110 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the controller 30 can understand and/or implement.

In various embodiments, the controller 30 is configured to control and/or in electrical communication with the voltage sources 50, cryogenic system and/or vacuum system 40 controlling the temperature and/or pressure within the cryogenic and/or vacuum chamber 40, manipulation sources, and/or other systems controlling various environmental conditions (e.g., temperature, pressure, and/or the like) within the cryogenic and/or vacuum chamber 40 and/or configured to manipulate and/or cause a controlled evolution of quantum states of one or more quantum objects within the confinement apparatus. For example, the controller 30 may cause a reading procedure comprising coherent shelving to be performed, possibly as part of executing a quantum circuit and/or algorithm. In various embodiments, the atomic objects confined within the confinement apparatus are used as qubits of the quantum computer 110.

### Example Atomic Object Confinement Apparatus

In various embodiments, the atomic object confinement apparatus comprises a plurality of electrodes that are configured to generate a confining potential. For example, the controller 30 may control the voltage sources 50 to provide electrical signals to the electrodes of the atomic object confinement apparatus such that the electrodes generate a confining potential. The confining potential is configured to confine a plurality of atomic objects within a confinement volume defined by the atomic object confinement apparatus. For example, in an example embodiment, the atomic object confinement apparatus is a surface ion trap, and the confinement volume is a volume located proximate the surface of the surface ion trap. In various embodiments, the electrodes and/or confining potential are configured to define a plurality of atomic object positions within the confinement volume.

In various embodiments, the atomic object positions are disposed in a one-dimensional or two-dimensional lay out. For example, in an example embodiment, the atomic object positions are disposed along an axis of a linear atomic object confinement apparatus. In another example embodiment, the atomic object positions are disposed in a two-dimensional array or layout defined by a two-dimensional atomic object confinement apparatus.

In various embodiments, the confining potential evolves with time, based on the electrical signals provided to the electrodes by the voltage sources 50. The evolving of the confining potential may be configured to cause one or more atomic objects to move from respective first atomic object positions to respective second atomic object positions. An example two-dimensional atomic object confinement apparatus 120, for example, may comprise sequences of electrodes that are separated by a spacing factor. In an example embodiment, the spacing factor is in a range between 500 μm and 1000 μm (e.g., approximately 750 μm). The sequences of electrodes may define a plurality of atomic object positions. In various embodiments, an atomic object position is a volume corresponding to a portion of an atomic object path where the electrodes are configured to maintain an atomic object (e.g., as part of an atomic object crystal) and/or a pair or set of atomic objects (e.g., for performing two or more qubit gates) for the performance of a function of the quantum computer and/or to store one or more atomic objects during the performance of functions of the quantum computer on other atomic objects located at other atomic positions.

In various embodiments, the voltage sources 50 provide electrical signals to the potential generating elements (e.g., electrodes) of the confinement apparatus 120, such that a confining potential is formed. Based on the contours and time evolution of the confining potential one or more atomic objects are confined at respective atomic object positions, moved between atomic object positions and/or the like. When an atomic object is located at an atomic object position, one or more functions (e.g., quantum computing functions) may be performed on the atomic object. An example function that may be performed on an atomic object is photoionization of the atomic object. For example, a manipulation signal may be applied to the atomic object to photo ionize the atomic object.

Another example function that may be performed on an atomic object is state preparation of the atomic object. For example, one or more manipulation signals may be applied to the atomic object to prepare the atomic object in a particular quantum state. For example, the particular quantum state may be a state within a defined qubit space used by the quantum computer such that the atomic object may be used as a qubit of the quantum computer.

Another example function that may be performed on an atomic object is reading a quantum state of the atomic object. For example, a manipulation signal (e.g., a reading signal) may be applied to the atomic object. When the atomic object's wave function collapses into a first state of the qubit space, the atomic object will fluoresce in response to the reading signal being applied thereto. When the atomic object's wave function collapses into a second state of the qubit space, the atomic object will not fluoresce in response to the reading signal being applied thereto.

Another example function that may be performed on an atomic object is cooling the atomic object or an atomic object crystal comprising the atomic object. An atomic object crystal is a pair or set of atomic objects where one of the atomic objects of the atomic object crystal is qubit atomic object used as a qubit of the quantum computer and the one or more other atomic objects of the atomic object crystal are used to perform sympathetic cooling of the qubit atomic object. For example, a manipulation signal (e.g., a cooling signal or a sympathetic cooling signal) may be applied to the atomic object or atomic object crystal to cause the (qubit) atomic object to be cooled (e.g., reduce the vibrational and/or other kinetic energy of the (qubit) atomic object).

Another example function that may be performed on an atomic object is shelving the atomic object. In various embodiments, atomic objects in the second state of the qubit space may be shelved during the performance of a reading function. For example, a shelving operation may comprise causing the quantum state of an atomic object in the second state of the qubit space to evolve to an at least meta-stable state outside of the qubit space while a reading operation is performed. In various embodiments, the shelving of an atomic object is performed by applying one or more manipulation signals to the atomic object to cause the atomic object's quantum state to evolve to an at least meta-stable state outside of the qubit space when the atomic object is in the second state of the qubit space.

Another example function that may be performed on an atomic object is (optical) repumping of the atomic object. In various embodiments, repumping of the atomic object comprises applying one or more manipulation signals to the atomic object to cause the quantum state of the atomic object to evolve to an excited state.

Another example function that may be performed on an atomic object is performing a single qubit gate on the atomic object. For example, one or more manipulation signals may be applied to the atomic object to perform a single qubit quantum gate on the atomic object.

Another example function that may be performed on an atomic object is performing a two-qubit gate on the atomic object. For example, one or more manipulation signals may be applied to a pair or set of atomic objects that includes the atomic object to perform a two qubit (or three, four, or more) quantum gate on the atomic object and the at least one other atomic object.

In various embodiments, the atomic object confinement apparatus 120 comprises one or more signal manipulation elements. In various embodiments, the manipulation signals are provided transverse to a plane defined by a surface of the atomic object confinement apparatus 120 such that the manipulation signals are incident on corresponding signal manipulation elements. Each signal manipulation element is configured to, responsive to an incoming manipulation signal being incident thereon, induce an action signal that is emitted such that the action signal is directed to a respective atomic object position of the atomic object confinement apparatus 120 that corresponds to the signal manipulation element. The action signal is an appropriate signal (e.g., having an appropriate wavelength, polarization, amplitude, and/or the like) for causing the corresponding function to be performed responsive to the action signal (and possibly application of other action signals, magnetic fields, and/or the like) being incident on an atomic object (or set of atomic objects) at the corresponding atomic object position.

### Example Signal Management Systems

In various embodiments, a signal management system is configured to control the provision and/or collection of signals to and/or from respective atomic object positions defined by the atomic object confinement apparatus 120. In various embodiments, the signal management system defines optical paths used to provide signals to respective atomic object positions and/or collection signals emitted by atomic objects located at respective atomic object positions. The optical paths comprise respective signal manipulation elements. In various embodiments, the signal manipulation elements are configured to enable the optical paths to be transverse to the surface of the atomic object confinement apparatus.

Various embodiments are disclosed where the surface of the atomic object confinement apparatus 120 comprises one or more signal manipulation elements. For example, in various embodiments, the surface of the atomic object confinement apparatus 120 comprises an arrangement of signal manipulation elements for each atomic object position defined by the atomic object confinement apparatus 120.

In various embodiments, the atomic object confinement apparatus 120 comprises one or more signal manipulation elements. In various embodiments, one or more of the signal manipulations elements are metamaterial arrays and each metamaterial array comprises a plurality of metamaterial structures (e.g., photonic structures) which each define and/or comprise a respective metamaterial surface. The array of metamaterial structures (e.g., the composite surface formed by combining the respective metamaterial surfaces of the plurality of metamaterial structures) may form and/or provide a metasurface. The metasurface, for example, may be a photonic metasurface. A photonic metasurface may describe an engineered surface designed to manipulate light through coherent interference implemented through local control of the amplitude, phase, and/or polarization of reflected or transmitted light. This control is implemented by an array of optical scattering elements (e.g., the metamaterial structures), each of which have dimensions on the scale of the wavelength of light or smaller in at least one dimension, with spacing on the scale of the wavelength of light or smaller. For example, a photonic metasurface, as used herein, refers to the composite metasurface formed by the plurality of metamaterial structures (e.g., photonic structures) of a metamaterial array. The metamaterial structures of a metamaterial array are approximately wavelength or sub-wavelength (e.g., nanometer scale), high contrast structures (compared to other portions of the surface of the atomic object confinement apparatus 120) whose geometry, size, arrangement, and orientation control the phase, amplitude, and polarization of electromagnetic waves.

In various embodiments, the metamaterial structures (e.g., photonic structures) are Huygen's metamaterial structures. For example, in various embodiments, inside each of the metamaterial structures, an electric dipole and a magnetic dipole are induced, causing each metamaterial structure to generate an electromagnetic wave like a Huygen's wavelet when an appropriate electromagnetic beam, signal, wave, and/or the like is incident on the metamaterial structure. The phases of the magnetic dipole and the electric dipole determine the phase, direction, and/or polarization of the electromagnetic wave, radiation, beam, and/or signal emitted by the metamaterial structure. In various embodiments, one or more plasmonic photonic metasurfaces are used. For example, a negative plasmonic photonic metasurface (e.g., holes in a flat metal surface) may be etched into a metal surface and/or portion thereof of the surface of the atomic object confinement apparatus 120. In various embodiments, one or more photonic metasurfaces that are dielectric photonic metasurfaces configured to modify the geometric phase (e.g., Pancharatnam-Berry (PB) phase) using one or more electric or magnetic resonances are used. In various embodiments, dielectric photonic metasurfaces configured to modify propagation phase without resonance (e.g., truncated waveguides) are used. In various embodiments, the photonic metasurfaces are dielectric and/or plasmonic metasurfaces using two or more electric or magnetic resonances of any order to locally engineer the desired phase and amplitude response of the respective photonic metasurface. Various other types of metamaterial structures that define various types of metamaterial surfaces are used in various embodiments.

Photonic metasurfaces can be designed and/or configured to generate an electromagnetic wave, radiation, beam, and/or signal in a particular and/or designated direction due to the phases of the electric and magnetic dipoles, for example, being established at the surface of the component metamaterial structures. In various embodiments, the metamaterial structures comprise positive and/or negative structures that are shaped and/or sized such that the metamaterial array formed by the plurality of metamaterial structures is configured to provide an action signal to a respective atomic object position of the atomic object confinement apparatus responsive to an incoming signal being incident on at least a portion of the metamaterial array and/or to provide a collection signal to collection optics of the quantum computer responsive to an emitted signal being incident on at least a portion of the metamaterial array.

The photonic metasurfaces may be used to control the polarization of an induced signal (e.g., action signal and/or collection signal), focus and/or collimate the induced signal, chromatically filter the induced signal, control the phase of the induced signal, and/or the like.

### Example Method of Fabricating Photonic Devices

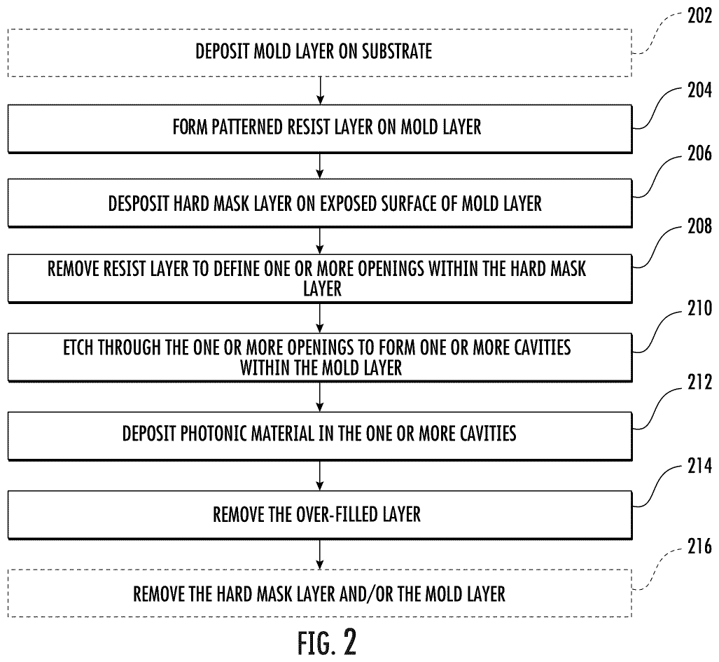

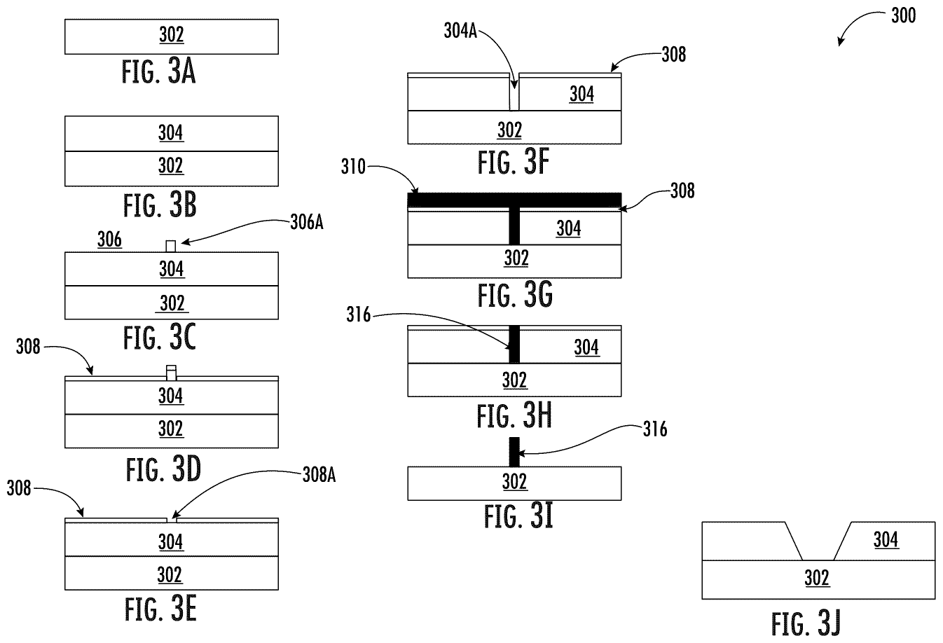

FIG. 2 provides a flowchart illustrating processes, procedures, operation, and/or the like for scalable photonic device fabrication in accordance with one example embodiment. Specifically, FIG. 2 provides a flowchart of a damascene fabrication process configured for robustness, repeatability, and compatibility with standard foundry processes. FIGS. 3A-3J provide cross-sectional views of various stages of fabricating example photonic device 300 in accordance with one example embodiment.

At step/operation 202, a mold layer 304 is deposited on a substrate 302, as shown in FIGS. 3B. For example, a damascene mold layer 304 comprising oxide, dielectric, and/or other material may be deposited on the substrate 302. For example, silicon (Si) may be deposited on the substrate 302 to form the mold layer 304. As another example, silicon dioxide (SiO₂) may be deposited on the substrate 302 to form the mold layer 304. As yet another example, silicon nitride (SiN) may be deposited on the substrate 302 to form the mold layer 304. In various embodiments, the mold layer 304 is a hard mold layer (e.g., formed from hard mold material). A hard mold material may have better mechanical properties relative to other materials. For example, a hard mold material may have better mechanical properties than resist. A high aspect ratio feature of resist, for example, a tall and narrow wall, may collapse or warp. The same feature made of a hard mold material may hold its form as desired. This enables patterning with higher aspect ratio mold structures. Another example of this is isolated mold structures, like a single pillar. A hard mold material will stay structurally sound for pillars (generally isolated structures) with higher aspect ratio (height/width) than a polymer resist material mold.

The substrate 302 may comprise any suitable material. For example, the substrate 302 may comprise any material suitable for an integrated circuit and/or other applications. Non-limiting examples of materials that can be used to form the substrate 302 include SiO2, Al2O3, SiN, SiC, Si, Ag, Au, Al, Pt, dielectric reflecting coating (e.g., interference based), and/or the like. For example, the substrate may comprise transparent material (e.g., SiO2, Al2O3, SiN, SiC, Si, and/or the like), reflective material (e.g., Ag, Au, Al, Pt, dielectric reflecting coating, and/or the like), and/or the like.

The mold layer 304 may be deposited onto the substrate 302 using one or more of a variety of techniques. For example, the mold layer 304 may be deposited onto the substrate 302 using spin-coating, roller coating, chemical vapor deposition, and/or other like. In one example, to form the mold layer 304 on the surface of the substrate 302, one or more drops of the mold layer 304 material may be deposited on the surface of the substrate 302. The substrate 302 may then be spun, for example, at a high rate so that the one or more drops of the mold layer 304 material become dispersed across the surface of the substrate 302. For example, the mold layer 304 may be evenly dispersed across the surface of the substrate 302.

In some embodiments, the mold layer 304 may be the substrate. In such some embodiments, a mold layer 304 is not deposited on a substrate. In this regard, in such some embodiments, step/operation 202 may not be performed. For example, the mold layer 304 may define or otherwise form a substrate.

The step/operation 202 may, or may not, result in the mold layer 304 being deposited such that the exposed surface requires smoothing or flattening. In this regard, if the exposed surface is to be smooth or flattened, an optional polishing step may occur. For example, the exposed surface of the mold layer 304 may be polished using chemical mechanical polishing (CMP) and/or other techniques to smoothen and/or flatten the exposed surface. For example, CMP and/or other techniques may be applied to planarize the mold layer 304.

In some embodiments, the mold layer 304 is deposited using one or more techniques that enables desired thickness and/or thickness uniformity to be achieved. Additionally or alternatively, one or more polishing operations may be applied to the mold layer 304 to achieve low surface roughness, desired thickness and/or thickness uniformity across the mold layer 304. FIG. 3A illustrates a cross-section before completion of the optional step/operation 202, and FIG. 3B illustrates a cross-section after completion of step/operation 202. Specifically, FIG. 3A illustrates a cross-section of a substrate 302 before deposition of the mold layer 304.

In some embodiments, a mask layer defining one or more openings 308A is formed on a surface of the mold layer 304. In some embodiments, the one or more openings expose one or more select portions of the surface of the mold layer 304. The mask layer may comprise a hard mask material (e.g., nitride, oxide, metal, and/or other durable material), a photoresist material (or other polymer material), and/or other materials suitable for facilitating and/or supporting etching of the mold layer 304. The mask layer, for example, may function as a protective layer and/or a patterning layer to facilitate etching of the mold layer 304.

In some embodiments, the mask layer comprises a patterned hard mask layer. In some embodiments, the mask layer comprises a patterned photoresist layer (or other polymer-based etch mask). The mask layer may be formed on the mold layer 304 using one or more techniques. In some embodiments, the mask layer is formed on the mold layer 304 by depositing a polymer-based etch mask on the mold layer 304. In some embodiments, depositing a polymer-based etch mask on the mold layer 304 comprises depositing etched photoresist layer (e.g., etched layer of photoresist material) on the mold layer 304. In some embodiments depositing a polymer-based etch mask on the mold layer 304 comprises depositing a photoresist layer (e.g., layer of photoresist material) on the mold layer and etching the photoresist layer. In some embodiments, the mask layer is formed on the mold layer 304 by depositing an etched hard mask layer (e.g., layer of hard mask material) on the mold layer 304, wherein the etched hard mask layer represents the mask layer. In some embodiments, the mask layer may be formed in accordance with the steps/operations 204-208. For example, in some embodiments, the mask layer may comprise a patterned hard mask layer that is formed on the mold layer 304 in accordance with the steps/operations 204-208 described below.

At step/operation 204, a patterned resist layer 306 is formed on the mold layer 304. In some embodiments, the patterned resist layer 306 comprises one or more resist structures. For example, one or more resist structures may be formed on the mold layer 304. In some embodiments, forming the patterned resist layer 306 comprises depositing a resist layer and patterning the resist layer. For example, a resist deposition and patterning operation may be performed to deposit and pattern the resist layer on the mold layer 304. One or more of a variety of techniques may be leveraged to form the patterned resist layer 306 onto the mold layer 304. For example, depositing the resist layer on the mold layer may comprise performing one or more of photolithography, electron beam lithography (EBL), nanoimprint lithography, and/or the like. For example, depositing the resist layer on the mold layer 304 may comprise performing any of a variety of lithography techniques. In some embodiments, forming the patterned resist layer 306 comprises depositing a planar layer using one or more techniques (e.g., spin coating, spray coating, and/or the like), and then patterning using lithographic. A lithographic technique, for example, may include multiple steps (e.g., exposure, development, and/or the like.). In some embodiments, the one or more resist structures may comprise photoresist material.

The one or more resist structures may be positioned on one or more select portions of the surface of the mold layer 304. For example, only certain portions of the mold layer 304 may have a resist structure formed thereon. For example, portions of the mold layer 304 designated for subsequent etching may have a resist structure disposed thereon, while other portions may remain exposed (e.g., portions of top surface of the mold layer 304 may be exposed while other portions of the top surface of the mold layer 304 may be covered by the one or more resist structures). For example and as shown in FIG. 3C, the mold layer 304 may have a single resist structure 306A formed thereon. As another example, the mold layer 304 may have a plurality of resist structures formed thereon. The plurality of resist structures may be spaced-apart from each other.

At step/operation 206, a hard mask layer 308 is deposited onto the mold layer 304. For example, a hard mask layer 308 may be deposited onto the exposed surface of the mold layer 304 to protect (e.g., during subsequent etching operation and/or other operations) the portion of the mold layer 304 corresponding to the exposed surface of the mold layer 304. In some embodiments, the step/operation 206 may, or may not, result in the hard mask layer 308 material being deposited onto the top surface of the one or more resist structures as well. For example, a hard mask layer depositing technique, which comprises depositing the hard mask layer 308 material on the mold layer 304 and the one or more resist structures, may be leveraged to ensure the hard mask layer 308 is deposited across the exposed surface of the mold layer 304 without voids. In some embodiments, the hard mask layer 308 has a thickness that is less than the thickness of each of the one or more resist structures. For example, the one or more resist structures may have a thickness that is larger than or equal to the thickness of the hard mask layer 308. The hard mask layer, for example, may comprise a thin layer. In one example embodiment, the hard mask layer 308 has a thickness that is about ⅕^{th} of the thickness of a resist structure. It should be understood that in other embodiments, the hard mask layer 308 may have a thickness that is greater than ⅕^{th} of the thickness of a resist structure or may have a thickness that is less than ⅕^{th} of the thickness of a resist structure.

The hard mask layer 308 may be of the same material as the mold layer 304 or it may be of a different material. For example, the hard mask layer 308 may comprise SiN. As another example, the hard mask layer 308 may comprise SiON. As yet another example, the hard mask layer 308 may comprise SiO2. In some embodiments, photolithography and/or other suitable techniques is leveraged to deposit the hard mask layer 308 onto the mold layer 304. FIG. 3D illustrates a cross-section after completion of step/operation 206.

At step/operation 208, the resist layer 306 is removed to define one or more openings 308A within the hard mask layer 308. For example, the one or more resist structures of the resist layer 306 are removed to expose the surface of the mold layer 304 directly below the one or more resist structures. For example, step/operation 208 may be configured to define one or more openings 308A within the hard mask layer that expose the one or more select portions of the surface of the mold layer (e.g., described in step/operation 204). One or more techniques (e.g., photolithography, lift off, and/or the like) may be leveraged to remove the one or more resist structures such that the hard mask layer 308 defines one or more openings 308A corresponding to the removed resist structures. For example, a hard mask lift-off operation may be performed to define the one or more openings 308A within the hard mask layer 308 corresponding to the one or more select portions of the mold layer. FIG. 3E illustrates a cross-section after completion of step/operation 208. Specifically, FIG. 3E illustrates a mask layer (as described above), which may comprise a patterned hard mask layer formed in accordance with the steps/operation 204-208 or other techniques as described above, a patterned photoresist layer formed in accordance with one or more techniques as describe above, or other suitable mask layer.

At step/operation 210, the one or more openings 308A are etched through to form one or more cavities 304A within the mold layer 304. For example, an etching operation (e.g., anisotropic etching and/or the like) may be performed on portions of the mold layer 304 directly below the one or more openings 308A within the hard mask layer 308 in order to define inverted metasurface features. In some embodiments, the etching operation may comprise a dry etching operation. In some embodiments, the etching operation may comprise etching vertically through the one or more openings 308A to the top surface of the substrate 302 to form one or more cavities 304A having a vertical mold profile. The one or more cavities 304A, for example, may comprise vertical side walls (e.g., substantially vertical side walls). As described above, in some embodiments, an etch stop layer may be deposited between the mold layer 304 and the substrate 302. In such some embodiments, the etch will slow and stop when the etch stop layer is reached, preventing the etch from proceeding into the substrate 302.

In some embodiments, SF₆ (with or without O₂) and/or C₄F₈ passivation may be leveraged to etch through the one or more openings 308A. For example, SF₆ (with or without O₂) and/or C₄F₈ passivation may be utilized in the etching process when the mold layer 304 is formed from Si. In some embodiments, CHF₃ (with O₂) may be leveraged to etch through the one or more openings 308A. For example, CHF₃ (with O₂) may be utilized in the etching process when the mold layer 304 is formed from SiN. In some embodiments, SF₆, CF₄, CHF₃ (with O₂), and/or Ar may be leveraged to etch through the one or more openings 308A. For example, SF₆, CF₄, CHF₃ (with O₂), and/or Ar may be utilized in the etching process when the mold layer 304 is formed from SiO₂. It should be understood that other etching materials and/or techniques may be leveraged to etch through the one or more openings 308A to form one or more cavities 304A within the mold layer 304.

In some embodiments, step/operation 210 results in one or more cavities 304A with a high aspect ratio. For example, an etching operation may be performed on the mold layer 304 to create one or more cavities 304A (e.g., mold layer cavities) with a high aspect ratio. As described above and shown in FIG. 3F, the one or more cavities 304A may have a vertical mold profile (e.g., the one or more cavities 304A may have vertical side walls) in some embodiments. In one example embodiment, and as shown in FIG. 3J, the one or more cavities 304A may have salient profile such as, for example, a trapezoidal profile. For example, a cavity (e.g., one or more of the cavities 304A) may be larger at the top than at the bottom, which in turn makes it easier to fill the cavity without the formation of voids. The salient profile, for example, may enable less-conformal deposition process (e.g., for depositing photonic/metasurface material) to be utilized at subsequent processes. An example of a less-conformal deposition process that may be enabled by a salient mold profile is Pulsed Laser Deposition (PLD). More generally, physical vapor deposition (PVD) processes may be enabled by a salient mold profile. A salient mold profile enables filling of the mold using a non-conformal deposition. Additionally, the salient profile may enable deposition of photonic material in the one or more cavities 304A without forming voids. In some embodiments, the salient profile of the one or more cavities 304A may be formed by tailoring of a plasma etch process. In some embodiments, the salient profile of the one or more cavities 304A may be formed by selective wet etching (e.g., KOH etching of Si, and/or the like). It should be understood that other techniques and/or combinations of techniques may be leveraged to achieve the salient profile. In some embodiments, the profile of the one or more cavities 304A may comprise other profiles (e.g., not trapezoidal or vertical mold profile) configured to enable less-conformal deposition process to be utilized to deposit photonic materials in the one or more cavities 304A. FIG. 3F illustrates a cross-section after completion of step/operation 210. As used herein, the terms photonic material and metasurface material may be used interchangeably. For example, photonic material may comprise metasurface material.

At step/operation 212, a photonic material is deposited into the one or more cavities 304A within the mold layer 304 to fill the one or more cavities 304A. One or more techniques may be leveraged to deposit photonic material in the one or more cavities 304A. In an example embodiment, a conformal technique (e.g., atomic layer deposition, chemical vapor deposition, and/or the like) is leveraged to deposit photonic material in the one or more cavities 304A. For example, photonic material may be deposited using a technique that ensures that the deposition is conformal (e.g., to ensure all surfaces are uniformly coated). For example, a damascene atomic layer deposition process/operation may be performed to fill the one or more cavities 304A with photonic material to form phonic structures (e.g., metasurface(s)), such that all surfaces ac uniformly coated. In another example embodiment, non-conformal technique such as physical vapor deposition (e.g., sputtering, evaporation, pulsed laser deposition, and/or the like) is leveraged to deposit photonic material in the one or more cavities 304A. In yet another example embodiment, wet deposition (e.g., spin on, spray, sol-gel processing) is leveraged to deposit photonic material in the one or more cavities 304A. The photonic material may be any of a variety of materials. For example, the photonic material may comprise dielectrics, metals, semiconductors, and/or the like. In one example embodiment, non-limiting examples of the photonic material include TiO2, HFO2, ITO, and/or the like. By utilizing a hard-mask mold material, example embodiments of the present disclosure allow for high-temperature conformal depositions which in turn enables the use of materials such as III-V compound semiconductors (e.g., GaN, GaAs, AlN, and/or the like).

In some embodiments and as illustrated in FIG. 3G, depositing the photonic material comprises overfilling the one or more cavities 304A. For example, the one or more mold layer cavities may be over-filled to ensure that each of the one or more cavities 304A within the mold layer 304 is completely filled without any void. For example, depositing the photonic material may comprise filling the one or more cavities 304A from a bottom wall of the one or more cavities, and then overfilling to form an over-filled layer 310 on the hard mask layer 308. In this regard, the photonic material may be deposited to fill the one or more cavities 304A and then overfill to form an over-filled layer 310 (e.g., comprising the photonic material) on the hard mask layer 308. FIG. 3G illustrates a cross-section after completion of step/operation 212.

Step/operation 212 may, or may not, result in photonic material being deposited such that the over-filled layer 310 requires smoothing or flattening. If the exposed surface is to be smooth or flattened, an optional polishing step may occur. For example, the over-filled layer 310 may be polished using CMP and/or other techniques to smoothen, flatten, and/or planarize the over-filled layer 310. In some embodiments, one or more polishing techniques may be performed on the over-filled layer 310 to achieve low surface roughness and improve thickness uniformity. For example, one or more polishing techniques may be performed on the over-filled layer 310 to improve the thickness uniformity. If the optional step does not occur due to over-filled layer 310 not needing to be smoothed or flattened, the process continues step/operation 214 shown in FIG. 2.

At step/operation 214, the over-filled layer 310 is removed. For example, the over-filled layer 310 may be etched back or otherwise removed to expose the hard mask layer 308 and one or more photonic structures 316 formed within the mold layer 304. FIG. 3H illustrates a cross- section after completion of step/operation 214.

At step/operation 216, the hard mask layer 308 and/or the mold layer 304 is optionally removed. For example, the hard mask layer 308 and/or the mold layer 304 may be etched or otherwise selectively removed. For example, in some embodiments and as shown in FIG. 31, the hard mask layer 308 and the mold layer 304 are removed. FIG. 31 illustrates a cross-section after completion of step/operation 216, wherein the hard mask layer 308 and the mold layer 304 are removed. In some embodiments, the hard mask layer 308 is removed before depositing the photonic material. In some embodiments, the hard mask layer 308 is removed after depositing the photonic material. In some embodiments, the mold layer 304 may be removed via selective etching that chemically removes the mold layer with minimal chemical interaction with either the substrate or photonic material.

In some embodiments where the mold layer 304 is removed, cladding with a low-index material may be desired. For example, index contrast between the device material and cladding material may be critical to achieving certain photonic responses. Claddings, like SiO2 cladding, have refractive index much higher than air/vacuum. There may be applications in which cladding is required for device protection (e.g., if device is in intermediate layer with other layer(s) on top). In this regard, it may be advantageous to use a cladding with refractive index similar to air, for example. Porous materials such as, for example, aerogel may be used. Aerogel, for example, can have refractive index barely higher than air, as it consists of a coarse network of fibers. In some examples, a final cladding layer (e.g., SiO2 cladding) may be deposited on the aerogel cladding for improved performance.

In such some embodiments, after the mold layer is removed, low-index cladding layer (e.g., aerogel layer, and/or the like) is deposited. In some embodiments, depositing the low-index cladding layer comprises multiple steps (e.g., introduction of a liquid precursor, conversion of that precursor to a wet gel, conversion to an aerogel (supercritical drying), and/or the like). The low-index cladding layer (e.g., aerogel layer) may be deposited such that it fills or partially fills regions between device structures and extend some distance above the top of the device layer. A top layer material may then be deposited on the low-index cladding layer. In some embodiments, this top layer could be any of a wide range of materials. For example, the top layer may comprise SiO2 (e.g., where further layers would be added to the wafer, or to allow it to be handled/cleaned as a glass device). In this regard, some example embodiments of the present disclosure allows cladding of the photonic device in a material with index similar to that of air/vacuum, while also providing a final surface consisting of a more conventional material and enabling further processing or indelicate handling/cleaning.

In some embodiments where the mold layer 304 is not removed, for example, where the mold layer 304 is left in place to serve as interstitial cladding and the mold layer 304 is the same material as the layer underneath it (e.g., SiO2 hard mold on SiO2 surface), an etch stop layer is deposited between the mold layer 304 and the underlying layer (e.g., substrate 302). An etch stop may describe a thin material layer that is resistant to the etch used to pattern the mold layer. In such embodiments, depositing an etch stop layer between the mold layer 304 and the underlying layer (e.g., substrate) helps in controlling the etched depth of the mold layer 304. In such some embodiments, an etch stop layer deposition step/operation may be performed before step/operation 202. For example, an etch stop layer (e.g., thin Al2O3 layer) may be deposited on the substrate 302 (e.g., comprising SiO2) and a mold layer 304 (e.g., comprising SiO2) may then be deposited on the etch stop layer. In this regard, when the mold layer 304 is etched (e.g., at step/operation 210), the etch will slow and stop when the etch stop layer is reached, preventing the etch from proceeding into the SiO2 underlayer (e.g., substrate 302).

In some embodiments, a first cladding layer (not shown in FIGS. 3A-31) may be formed on the substrate 302 subsequent to removing the mold layer. For example, the photonic structure(s) may be embedded within the first cladding layer. In some embodiments, the hard mask layer 308 and/or the mold layer 304 is not be removed. In some embodiments, the mold layer 304 may form a first cladding layer. For example, the mold layer 304 may comprise or otherwise formed from desired material for cladding. For example, the mold layer 304 may comprise silicon dioxide, glass, and/or other material that form a first cladding layer disposed on the substrate 302. In some embodiments, a top cladding layer (not shown) may be disposed on the first cladding layer. For example, the top cladding layer and the first cladding layer may enclose the one or more photonic structures 316. For example, the top cladding layer may be deposited using physical vapor deposition technique. As another example, the top cladding layer may be deposited using vapor deposition techniques. As yet another example, the top cladding layer may be deposited using liquid solution-based processing techniques. It should be understood that the top cladding layer may be deposited using other techniques and/or combination of techniques.

In some embodiments, a plurality of cladding layers may be deposited on the substrate. For example, one or more of a first cladding layer, interstitial cladding layer, and/or final layer may be deposited on the substrate 302. In some embodiments, the first cladding layer is the final cladding layer. In some embodiments, the final cladding layer is planarized. For example, one or more polishing operations may be performed on the final cladding layer to planarize the final cladding layer. For example, the final cladding layer may be planarized to prepare for deposition of a lithographic layer. For example, planarizing the final cladding layer may remove material to create a planar surface at the height defined by the photonic structure (e.g., so the photonic structure and interstitial cladding form a uniform and void-free surface). In such some embodiments, where the first cladding layer is planarized, a top cladding layer may not be deposited on the top cladding layer.

As described above, the hard mask layer 308 may be patterned using additive patterning technique. In some embodiments, subtractive patterning technique may be leveraged to pattern the hard mask layer 308. In such some embodiments, the step/operation 206 may be performed before step/operation 204. For example, a hard mask layer 308 may be deposited on the mold layer 304 and then a resist layer 306 (e.g., comprising one or more resist structures) may be patterned on the hard mask layer 308. In such some embodiments, the hard mask layer 308 is then etched (e.g., using resist as an etch mask). The resist layer is then removed, leaving a patterned hard mask, which may be used to subsequently mask etching of the mold layer 304.

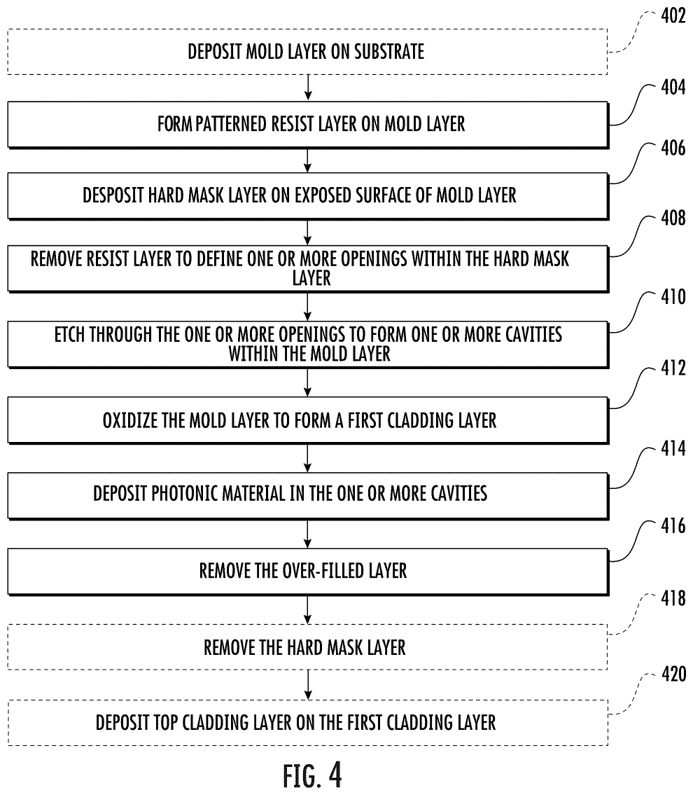

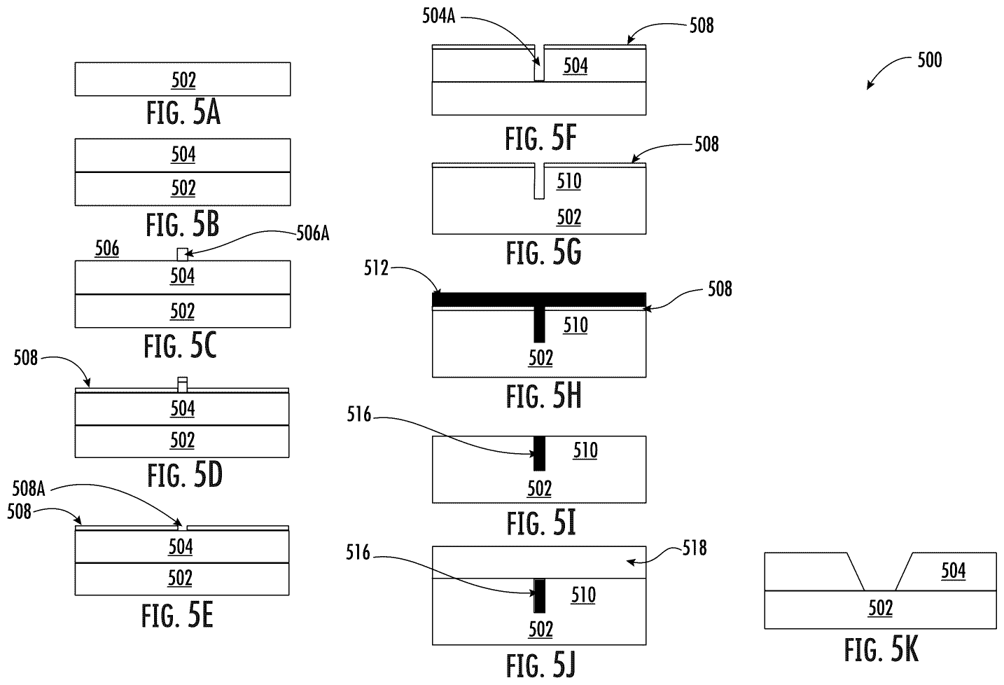

FIG. 4 provides a flowchart illustrating processes, procedures, operation, and/or the like for scalable photonic device fabrication in accordance with another example embodiment. Specifically, FIG. 4 provides a flowchart of a damascene fabrication process configured for robustness, repeatability, and compatibility with standard foundry processes. FIGS. 5A-5K provide cross-sectional views of various stages of fabricating example photonic device 500 in accordance with one example embodiment.

At step/operation 402, a mold layer 504 is deposited on the substrate 502, as shown in FIGS. 5B. For example, a damascene mold layer 504 comprising oxide, dielectric, and/or other material may be deposited on the substrate 502. For example, silicon (Si), amorphous silicon, or the like may be deposited on the substrate 502 to form the mold layer 504. In various embodiments, the mold layer 504 is a hard mold layer.

The substrate 502 may comprise any suitable material. For example, the substrate 502 may comprise any material suitable for an integrated circuit and/or other application. Non-limiting examples of materials that can be used to form the substrate 502 include SiO2, Al2O3, SiN, SiC, Si, Ag, Au, Al, Pt, dielectric reflecting coating (e.g., interference based), and/or the like. For example, the substrate 502 may comprise transparent material (e.g., SiO2, Al2O3, SiN, SiC, Si, and/or the like), reflective material (e.g., Ag, Au, Al, Pt, dielectric reflecting coating, and/or the like), and/or the like.

The mold layer 504 may be deposited onto the substrate 502 using one or more of a variety of techniques. For example, the mold layer 504 may be deposited onto the substrate 502 using spin-coating, roller coating, chemical vapor deposition, and/or other like. In one example, to form the mold layer 504 on the surface of the substrate 502, one or more drops of the mold layer 504 material may be deposited on the surface of the substrate 502. The substrate 502 may then be spun, for example, at a high rate so that the one or more drops of the mold layer 504 material become dispersed across the surface of the substrate 502. For example, the mold layer 504 may be evenly dispersed across the surface of the substrate 502.

In some embodiments, the mold layer 504 may be the substrate. In such some embodiments, a mold layer 504 is not deposited on a substrate. In this regard, in such some embodiments, step/operation 202 may not be performed. For example, the mold layer 304 may define or otherwise form a substrate.

The step/operation 402 may, or may not, result in the mold layer 504 being deposited such that the exposed surface requires smoothing or flattening. In this regard, if the exposed surface is to be smooth or flattened, an optional polishing step may occur. For example, the exposed surface of the mold layer 504 may be polished using chemical mechanical polishing (CMP) and/or other techniques to smoothen and/or flatten the exposed surface. For example, CMP and/or other techniques may be applied to planarize the mold layer 504.

In some embodiments, the mold layer 504 is deposited using one or more techniques that enables desired thickness and/or thickness uniformity to be achieved. Additionally or alternatively, one or more polishing operations may be performed on the mold layer 504 to achieve low surface roughness, desired thickness and/or thickness uniformity across the mold layer 504. FIG. 5A illustrates a cross-section before completion of step/operation 402, and FIG. 5B illustrates a cross-section after completion of step/operation 402. Specifically, FIG. 5A illustrates a cross-section of a substrate before deposition of the mold layer 504.

In some embodiments, an etch stop layer is deposited between the mold layer 504 and the underlying layer (e.g., substrate 502). As noted above, an etch stop may describe a thin material layer that is resistant to the etch used to pattern the mold layer. Depositing an etch stop layer between the mold layer 504 and the substrate 502 helps in controlling the etched depth of the mold layer 504 at subsequent step(s)/operation(s). In such some embodiments, an etch stop layer deposition step/operation may be performed before step/operation 402. For example, an etch stop layer (e.g., thin Al2O3 layer) may be deposited on the substrate 502 (e.g., comprising SiO2) and a mold layer 504 (e.g., comprising SiO2) may then be deposited on the etch stop layer. In this regard, when the mold layer 504 is etched (e.g., at step/operation 410), the etch will slow and stop when the etch stop layer is reached, preventing the etch from proceeding into the SiO2 underlayer (e.g., substrate 502).

In some embodiments, a mask layer defining one or more openings 508A is formed on a surface of the mold layer 304. In some embodiments, the one or more openings 508A expose one or more select portions of the surface of the mold layer 504. The mask layer may comprise a hard mask material (e.g., nitride, oxide, metal, and/or other durable material), a photoresist material (or other polymer material), and/or other materials suitable for facilitating and/or supporting etching of the mold layer 504. The mask layer, for example, may function as a protective layer and/or a patterning layer to facilitate etching of the mold layer 504.

In some embodiments, the mask layer comprises a patterned hard mask layer. In some embodiments, the mask layer comprises a patterned photoresist layer (or other polymer-based etch mask). The mask layer may be formed on the mold layer 504 using one or more techniques. In some embodiments, the mask layer is formed on the mold layer 504 by depositing a polymer-based etch mask on the mold layer 504. In some embodiments, depositing a polymer-based etch mask on the mold layer 504 comprises depositing etched photoresist layer (e.g., etched layer of photoresist material) on the mold layer 504. In some embodiments depositing a polymer-based etch mask on the mold layer 504 comprises depositing a photoresist layer (e.g., layer of photoresist material) on the mold layer 504 and etching the photoresist layer. In some embodiments, the mask layer is formed on the mold layer 504 by depositing an etched hard mask layer (e.g., layer of hard mask material) on the mold layer 504, wherein the etched hard mask layer represents the mask layer. In some embodiments, the mask layer may be formed in accordance with the steps/operations 404-408. For example, in some embodiments, the mask layer may comprise a patterned hard mask layer that is formed on the mold layer 304 in accordance with the steps/operations 404-408 described below.

At step/operation 404, a patterned resist layer 506 is formed on the mold layer 504. In some embodiments, the patterned resist layer 506 comprises one or more resist structures. For example, one or more resist structures may be formed on the mold layer 504. In some embodiments, forming the patterned resist layer 306 comprises depositing a resist layer and then patterning the resist layer. For example, a resist deposition and patterning operation may be performed to deposit and pattern a resist layer on the mold layer 504. One or more of a variety of techniques may be leveraged to form the patterned resist layer 506 onto the mold layer 504. For example, depositing the resist layer on the mold layer may comprise performing one or more of photolithography, electron beam lithography (EBL), nanoimprint lithography, and/or the like. In some embodiments, forming the patterned resist layer 506 comprises depositing a planar layer using one or more techniques (e.g., spin coating, spray coating, and/or the like), and then patterning using lithographic. The lithographic technique, for example, may include multiple steps (e.g., exposure, development, and/or the like.). In some embodiments, the one or more resist structures may comprise photoresist material.

The one or more resist structures may be positioned on one or more select portions of the surface of the mold layer 504. For example, only certain portions of the mold layer 504 may have a resist structure formed thereon. For example, portions of the mold layer 504 designated for subsequent etching may have a resist structure disposed thereon, while other portions may remain exposed (e.g., portions of top surface of the mold layer 504 may be exposed while other portions of the top surface of the mold layer 504 may be covered by the one or more resist structures). For example and as shown in FIG. 5C, the mold layer 504 may have a single resist structure 506A formed thereon. As another example, the mold layer 504 may have a plurality of resist structures formed thereon. The plurality of resist structures may be spaced-apart from each other.

At step/operation 406, a hard mask layer 508 is deposited onto the mold layer 504. For example, a hard mask layer 508 may be deposited onto the exposed surface of the mold layer 504 to protect (e.g., during subsequent etching operation and/or other operations) the portion of the mold layer 504 corresponding to the exposed surface of the mold layer 504. In some embodiments, the step/operation 406 may, or may not, result in the hard mask layer 508 material being deposited onto the top surface of the one or more resist structures as well. For example, a hard mask layer depositing technique, which comprises depositing the hard mask layer 508 material on the mold layer 504 and the one or more resist structures, may be leveraged to ensure the hard mask layer 508 is deposited across the exposed surface of the mold layer 504 without voids. In some embodiments, the hard mask layer 508 has a thickness that is less than the thickness of each of the one or more resist structures. For example, the one or more resist structures may have a thickness that is larger than or equal to the thickness of the hard mask layer 508. The hard mask layer, for example, may comprise a thin layer. In one example embodiment, the hard mask layer 508 has a thickness that is about ⅕^{th} of the thickness of a resist structure. It should be understood that in other embodiments, the hard mask layer 508 may have a thickness that is greater than ⅕^{th} of the thickness of a resist structure or may have a thickness that is less than ⅕^{th} of the thickness of a resist structure. The hard mask layer 508 may be of the same material as the mold layer 504 or it may be of a different material. 504. FIG. 5D illustrates a cross-section after completion of step/operation 406.

At step/operation 408, the resist layer 506 is removed to define one or more openings 508A within the hard mask layer 508. For example, the one or more resist structures are removed to expose the surface of the mold layer 504 directly below the one or more resist structures. For example, step/operation 408 may be configured to define one or more openings 508A within the hard mask layer that expose the one or more select portions of the surface of the mold layer (e.g., described in step/operation 404).

One or more techniques (e.g., photolithography, lift off, and/or the like) may be leveraged to remove the one or more resist structures such that the hard mask layer 508 defines one or more openings 508A corresponding to the removed resist structures. For example, a hard mask lift-off operation may be performed to define the one or more openings 508A within the hard mask layer 508 corresponding to the select portions of the mold layer. FIG. 5E illustrates a cross-section after completion of step/operation 408. Specifically, FIG. 5E illustrates a mask layer (as described above), which may comprise a patterned hard mask layer formed in accordance with the steps/operation 404-408 or other techniques as described above, a patterned photoresist layer formed in accordance with one or more techniques as describe above, or other suitable mask layer.

At step/operation 410, the one or more openings 508A are etched through to form one or more cavities 504A within the mold layer 504. For example, an etching operation (e.g., anisotropic etching and/or the like) may be performed on portions of the mold layer 504 directly below the one or more openings 508A within the hard mask layer 508 to define inverted metasurface features. In some embodiments, the etching operation may comprise a dry etching operation. In some embodiments, the etching operation may comprise a wet etching operation. In some embodiments, the etching operation may comprise etching vertically through the one or more openings 508A to the surface of the substrate 502 to form one or more cavities 504A having a vertical mold profile. The one or more cavities 504A, for example, may comprise vertical side walls (e.g., substantially vertical side walls). As described above, in some embodiments, an etch stop layer may be deposited between the mold layer 504 and the substrate 502. In such some embodiments, the etch will slow and stop when the etch stop layer is reached, preventing the etch from proceeding into the substrate 502.

In some embodiments, SF₆ (with or without O₂) and/or C₄F₈ passivation may be leveraged to etch through the one or more openings 508A. For example, SF₆ (with or without O₂) and/or C₄F₈ passivation may be utilized in the etching process when the mold layer 504 is formed from Si. It should be understood that other etching materials and/or techniques may be leveraged to etch through the one or more openings 508A to form one or more cavities 504A within the mold layer 504. In some embodiments, step/operation 410 results in one or more cavities 504A with a high aspect ratio. For example, an etching operation may be performed on the mold layer 504 to create one or more cavities 504A (e.g., mold layer cavities) with a high aspect ratio. As described above and shown in FIG. 5F, the one or more cavities 504A may have a vertical mold profile (e.g., the one or more cavities 504A may have vertical side walls) in some embodiments. In one example embodiment and as shown in FIG. 5K, the one or more cavities 504A may have a salient profile (e.g., trapezoidal profile, and/or the like). For example, a cavity (e.g., one or more of the cavities 504A) may be larger at the top than at the bottom, which in turn makes it easier to fill the cavity without the formation of voids. The salient profile, for example, may enable less-conformal deposition process (e.g., for depositing photonic material) to be utilized at subsequent processes. Additionally, the salient profile may enable deposition of photonic material in the one or more cavities 504A without forming voids. In some embodiments, the salient profile of the one or more cavities 504A may be formed by tailoring of a plasma etch process. In some embodiments, the salient profile of the one or more cavities 504A may be formed by selective wet etching (e.g., KOH etching of Si). It should be understood that other techniques and/or combinations of techniques may be leveraged to achieve the salient profile. In some embodiments, the profile of the one or more cavities 504A may comprise other profiles (e.g., not trapezoidal or vertical mold profile) configured to enable less-conformal deposition process to be utilized to deposit photonic materials in the one or more cavities 504A. FIG. 5F illustrates a cross-section after completion of step/operation 410.

At step/operation 412, the mold layer 504 is oxidized to form a first cladding layer 510. For example, a mold layer 504 comprising Si may be oxidized to form a first cladding layer comprising SiO₂. For example, thermal oxidation may be applied to form a SiO₂ layer (e.g., first cladding layer 510). FIG. 5G illustrates a cross-section after completion of step/operation 412.

At step/operation 414, a photonic material is deposited into the one or more cavities 504A to fill the one or more cavities 504A. One or more techniques may be leveraged to deposit photonic material in the one or more cavities 504A. In an example embodiment, a conformal technique (e.g., atomic layer deposition, chemical vapor deposition, and/or the like) is leveraged to deposit photonic material in the one or more cavities 504A. For example, photonic material may be deposited using a technique that ensures that the deposition is conformal (e.g., to ensure all surfaces are uniformly coated). For example, a damascene atomic layer deposition process/operation may be performed to fill the one or more cavities 504A with a photonic material to form photonic structure(s), such that all surfaces ac uniformly coated. In another example embodiment, non-conformal technique such as physical vapor deposition (e.g., sputtering, evaporation, pulsed laser deposition, and/or the like) is leveraged to deposit photonic material in the one or more cavities 504A. In yet another example embodiment, wet deposition (e.g., spin on, spray, sol-gel processing) is leveraged to deposit photonic material in the one or more cavities 504A. As discussed with reference to FIG. 3, the photonic material may be any of a variety of materials. For example, the photonic material may comprise dielectrics, metals, semiconductors, and/or the like. In one example embodiment, non-limiting examples of the photonic material include TiO2, HFO2, ITO, and/or the like. In one example embodiment, molecular beam epitaxy (MBE) may be leveraged for deposition. An MBE, generally, describes an epitaxial growth/deposition method used to deposit materials that rely on precise stoichiometry and crystal structure. An MBE, for example, may be leveraged to deposit materials such as III-V compound semiconductors. In some embodiments and as illustrated in FIG. 5H, depositing the photonic material may comprise overfilling the one or more cavities 504A. For example, the one or more cavities 504A may be over filled to ensure that each of the one or more cavities 504A within the mold layer 504 is completely filled without any void. For example, depositing the photonic material may comprise filling the one or more cavities 504A from a bottom wall of the one or more cavities 504A, and then overfilling to form an over-filled layer 512 on the hard mask layer 508. In this regard, the photonic material may be deposited to fill the one or more cavities 504A and then overfill to form an over-filled layer 512 (e.g., comprising the photonic material) on the hard mask layer 508. FIG. 5H illustrates a cross-section after completion of step/operation 414.

Step/operation 414 may, or may not, result in photonic material being deposited such that the over-filled layer 512 requires smoothing or flattening. If the exposed surface is to be smooth or flattened, an optional polishing step may occur. For example, the over-filled layer 512 may be polished using CMP and/or other techniques to smoothen, flatten, and/or planarize the over-filled layer 512. In some embodiments, one or more polishing techniques may be performed on the over-filled layer 512 to achieve desired thickness uniformity or otherwise improve thickness uniformity. For example, one or more polishing techniques may be performed on the over-filled layer 512 to improve the thickness uniformity. If the optional step does not occur due to over-filled layer 512 not needing to be smoothed or flattened, the process continues step/operation 416 shown in FIG. 4.

At step/operation 416, the over-filled layer 512 is removed. For example, the over-filled layer 512 may be etched back or otherwise removed to expose the hard mask layer 508 and one or more photonic structures 516 formed within the mold layer 504/first cladding layer 510. FIG. 51 illustrates a cross-section after completion of step/operation 416.

At step/operation 418, the hard mask layer 508 is optionally removed. For example, the hard mask layer 508 may be etched or otherwise selectively removed. For example, in some embodiments and as shown in FIG. 51, the hard mask layer 508 is removed, exposing the top surface of the first cladding layer 510 and the one or more photonic structures 516. FIG. 51 illustrates a cross-section after completion of step/operation 418, wherein the hard mask layer 508 is removed. In some embodiments, the hard mask layer 508 is not be removed. In some embodiments, the hard mask layer 508 is removed before depositing the photonic material. In some embodiments, the hard mask layer 508 is removed after depositing the photonic material. In some embodiments, the mold layer 504 may be removed via selective etching that chemically removes the mold layer with minimal chemical interaction with either the substrate or photonic material.

At step/operation 420, a top cladding layer 518 is optionally deposited on the first cladding layer 510. For example, the top cladding layer 518 and the first cladding layer 510 may enclose the one or more photonic structures 516. The top cladding layer 518 may be deposited using one or more of a variety techniques. For example, the top cladding layer 518 may be deposited using physical vapor deposition technique. As another example, the top cladding layer 518 may be deposited using vapor deposition techniques. As yet another example, the top cladding layer 518 may be deposited using liquid solution-based processing techniques. It should be understood that the top cladding layer 518 may be deposited using other techniques and/or combination of techniques. In some embodiments, a plurality of cladding layers may be deposited on the substrate. For example, one or more of a first cladding layer, interstitial cladding layer, and/or final layer may be deposited on the substrate 502. In some embodiments, the first cladding layer is the final cladding layer. In some embodiments, the final cladding layer is planarized. For example, one or more polishing operations may be performed on the final cladding layer to planarize the final cladding layer. For example, the final cladding layer may be planarized to prepare for deposition of a lithographic layer. For example, planarizing the final cladding layer may remove material to create a planar surface at the height defined by the photonic structure (e.g., so the photonic structure and interstitial cladding form a uniform and void-free surface). In such some embodiments, where the first cladding layer is planarized, a top cladding layer may not be deposited on the top cladding layer.

As described above, the hard mask layer 508 may be patterned using additive patterning technique. In some embodiments, subtractive patterning technique may be leveraged to pattern the hard mask layer 508. In such some embodiments, the step/operation 406 may be performed before step/operation 404. For example, a hard mask layer 508 may deposited on the mold layer 504 and then a resist layer 506 (e.g., comprising one or more resist structures) may be patterned on the hard mask layer 508. In such some embodiments, the hard mask layer 508 is then etched (e.g., using resist as an etch mask). The resist layer is then removed, leaving a patterned hard mask, which may be used to subsequently mask etching of the mold layer 504.

In some embodiments, the damascene fabrication process is a double damascene fabrication process. For example, the damascene fabrication process may include at least two damascene steps. In such embodiments, the mold layer for the first damascene may comprise a soft mold (e.g., a photoresist, EBL, and/or the like) or may comprise a hard mold layer (as described in relation to FIGS. 2 and FIGS. 4). In this regard, such embodiments may enable the use of a mold material that is suitable or otherwise preferable to fabricate using damascene relative to via subtractive (e.g., etch-based and/or the like) process. This in turn, may allow or otherwise provide access to a larger range of materials that may be used as a damascene mold layer for the second damascene step. Such embodiments may be particularly suitable or otherwise advantageous if the mold layer comprises a cladding (e.g., the mold layer is a leave-on mold that represents a cladding for the respective application). Additionally, such embodiments, may be particular suitable or otherwise advantageous in applications where the mold layer is removed (e.g., by selective etching) to ensure removal of the mold layer without damaging the photonic structure(s) and/or substrate.

In some embodiments, the mold layer is removed after the first damascene step. A cladding layer is then deposited using conformal deposition and the overburden removed (e.g., second damascene step) to create a planar surface matching the height of the first damascene layer. In this regard, example embodiments of the present disclosure allow for a larger range of materials to be utilized and/or allows for use of materials that are easier to process. In some embodiments, the photonic device fabrication method includes depositing one or more interstitial cladding layers having a different material than the substrate and/or top cladding layer. Alternatively or additionally in some embodiments, the one or more interstitial cladding is formed using a layered process.

### Technical Advantages

Various embodiments provide technical solutions to the technical problems associated with fabrication of photonic devices. In various embodiments, apparatuses, systems, computer program products, and methods provide a damascene fabrication process specially configured for robustness, repeatability, scalability, and compatibility with foundry processes. For example, embodiments of the present disclosure provide damascene fabrication process that includes, patterning a resist layer on a mold layer, depositing a hard mask layer on the mold layer, etching the mold layer, and depositing photonic materials, which enables compatibility with photolithography and void-free cladding. Additionally, an example damascene fabrication process according to at least one embodiment includes polishing (e.g., surface polishing), which in turn enables desired thickness and thickness uniformity to be achieved. For example, by using a hard mask damascene, embodiments of the present disclosure provide for uniformity and thickness control.

### Exemplary Controller

In various embodiments, an atomic object confinement apparatus confinement apparatus 120 is incorporated into a system (e.g., a quantum computer 110) comprising a controller 30. In various embodiments, the controller 30 is configured to control various elements of the system (e.g., quantum computer 110). For example, the controller 30 may be configured to control the voltage sources 50, a cryogenic system and/or vacuum system controlling the temperature and pressure within the cryogenic and/or vacuum chamber 40, manipulation sources 60, cooling system, and/or other systems controlling the environmental conditions (e.g., temperature, humidity, pressure, and/or the like) within the cryogenic and/or vacuum chamber 40 and/or configured to manipulate and/or cause a controlled evolution of quantum states of one or more atomic objects confined by the atomic object confinement apparatus 120. In various embodiments, the controller 30 may be configured to receive signals from one or more optics collection systems.

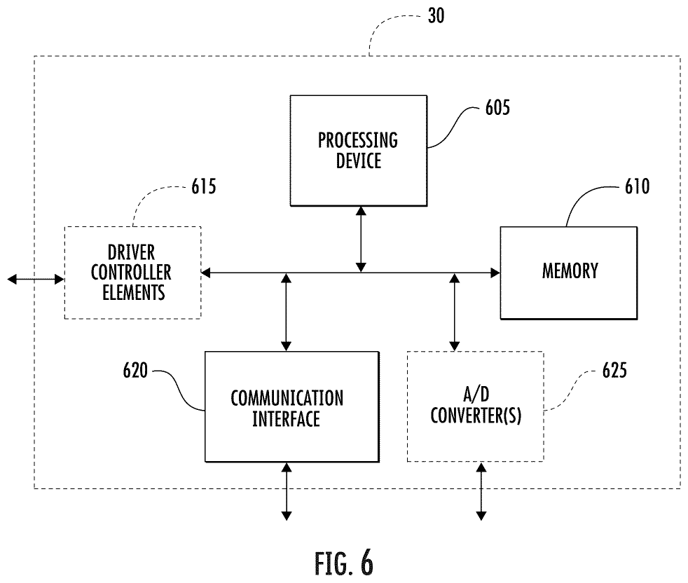

As shown in FIG. 6, in various embodiments, the controller 30 may comprise various controller elements including processing elements 605 (e.g., processing device), memory 610, driver controller elements 615, a communication interface 620, analog-digital converter elements 625, and/or the like. For example, the processing elements 605 may comprise programmable logic devices (CPLDs), microprocessors, coprocessing entities, application-specific instruction- set processors (ASIPs), integrated circuits, application specific integrated circuits (ASICs), field programmable gate arrays (FPGAs), programmable logic arrays (PLAs), hardware accelerators, other processing devices and/or circuitry, and/or the like. And/or controllers. The term circuitry may refer to an entirely hardware embodiment or a combination of hardware and computer program products. In an example embodiment, the processing element 605 of the controller 30 comprises a clock and/or is in communication with a clock.

For example, the memory 610 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 610 may store a queue of commands to be executed to cause a quantum algorithm and/or circuit to be executed (e.g., an executable queue), qubit records corresponding the qubits of quantum computer (e.g., in a qubit record data store, qubit record database, qubit record table, and/or the like), a calibration table, computer program code (e.g., in a one or more computer languages, specialized controller language(s), and/or the like), and/or the like. In an example embodiment, execution of at least a portion of the computer program code stored in the memory 610 (e.g., by a processing element 605) causes the controller 30 to perform one or more steps, operations, processes, procedures and/or the like described herein for providing manipulation signals to atomic object positions and/or collecting, detecting, capturing, and/or measuring indications of emitted signals emitted by atomic objects located at corresponding atomic object positions of the atomic object confinement apparatus 120.

In various embodiments, the driver controller elements 615 may include one or more drivers and/or controller elements each configured to control one or more drivers. In various embodiments, the driver controller elements 615 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 605). In various embodiments, the driver controller elements 615 may enable the controller 30 to operate a voltage sources 50, manipulation sources 60, cooling system, and/or the like. In various embodiments, the drivers may be laser drivers configured to operate one or manipulation sources 60 to generate manipulation signals; vacuum component drivers; drivers for controlling the flow of current and/or voltage applied to electrodes used for maintaining and/or controlling the trapping potential of the atomic object confinement apparatus 120 (and/or other drivers for providing driver action sequences to potential generating elements of the atomic object confinement apparatus); cryogenic and/or vacuum system component drivers; cooling system drivers, and/or the like. In various embodiments, the controller 30 comprises means for communicating and/or receiving signals from one or more optical receiver components (e.g., photodetectors of the optics collection system). For example, the controller 30 may comprise one or more analog-digital converter elements 625 configured to receive signals from one or more optical receiver components (e.g., a photodetector of the optics collection system), calibration sensors, and/or the like.

In various embodiments, the controller 30 may comprise a communication interface 620 for interfacing and/or communicating with a computing entity 10. For example, the controller 30 may comprise a communication interface 620 for receiving executable instructions, command sets, and/or the like from the computing entity 10 and providing output received from the quantum computer 110 (e.g., from an optical collection system) and/or the result of a processing the output to the computing entity 10. In various embodiments, the computing entity 10 and the controller 30 may communicate via a direct wired and/or wireless connection and/or via one or more wired and/or wireless networks 20.

### Exemplary Computing Entity

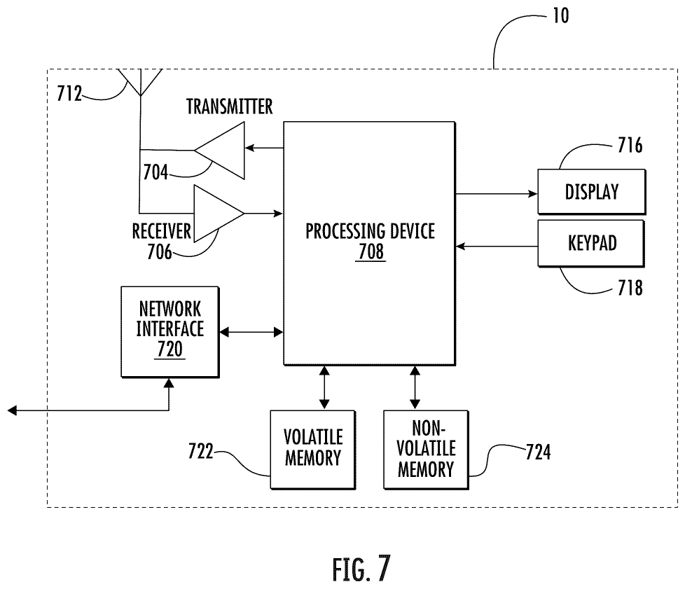

FIG. 7 provides an illustrative schematic representative of an example computing entity 10 that can be used in conjunction with embodiments of the present invention. In various embodiments, a computing entity 10 is configured to allow a user to provide input to the quantum computer 110 (e.g., via a user interface of the computing entity 10) and receive, display, analyze, and/or the like output from the quantum computer 110.

As shown in FIG. 7, a computing entity 10 can include an antenna 712, a transmitter 704 (e.g., radio), a receiver 706 (e.g., radio), and a processing element 708 (e.g., processing device) that provides signals to and receives signals from the transmitter 704 and receiver 706, respectively. The signals provided to and received from the transmitter 704 and the receiver 706, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division- Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

In various embodiments, the computing entity 10 may comprise a network interface 720 for interfacing and/or communicating with the controller 30, for example. For example, the computing entity 10 may comprise a network interface 720 for providing executable instructions, command sets, and/or the like for receipt by the controller 30 and/or receiving output and/or the result of a processing the output provided by the quantum computer 110. In various embodiments, the computing entity 10 and the controller 30 may communicate via a direct wired and/or wireless connection and/or via one or more wired and/or wireless networks 20.

The computing entity 10 may also comprise a user interface device comprising one or more user input/output interfaces (e.g., a display 716 and/or speaker/speaker driver coupled to a processing element 708 and a touch screen, keyboard, mouse, and/or microphone coupled to a processing element 708). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 718 (hard or soft), a touch display, voice/speech or motion interfaces, scanners, readers, or other input device. In embodiments including a keypad 718, the keypad 718 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 722 and/or non-volatile storage or memory 724, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Conclusion

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method for fabricating photonic devices, the method comprising:
forming a mask layer on a surface of a mold layer, the mask layer defining one or more openings, wherein the one or more openings expose one or more select portions of the surface of the mold layer;
etching through the one or more openings to form one or more cavities within the mold layer;
depositing photonic material within the one or more cavities, wherein depositing the photonic material comprises overfilling the one or more cavities to form an over-filled layer on the mask layer; and
removing the over-filled layer and the mask layer.

2. The method of claim 1, further comprising:
polishing the mold layer before forming the mask layer.

3. The method of claim 1, wherein depositing the photonic material comprises performing atomic layer deposition to fill the one or more cavities with the photonic material.

4. The method of claim 1, wherein depositing the photonic material comprises performing chemical vapor deposition to fill the one or more cavities with the photonic material.

5. The method of claim 1, further comprising:
removing the mold layer.

6. The method of claim 1, wherein the mold layer is formed from material suitable for cladding and comprises a first cladding layer.

7. The method of claim 6, further comprising:
depositing a top cladding layer on the first cladding layer.

8. The method of claim 1, wherein forming the mask layer on the mold layer comprises:
forming a patterned resist layer on the mold layer, the patterned resist layer comprising one or more resist structures positioned on the one or more select portions of the surface of the mold layer;
depositing a hard mask layer on the mold layer; and
removing the one or more resist structures to define the one or more openings.

9. The method of claim 8, wherein the one or more resist structures comprises a plurality of resist structures that are spaced apart and distributed across the mold layer, and wherein the hard mask layer has a thickness that is less than the thickness of each of the one or more resist structures.

10. The method of claim 1, wherein the mask layer comprises an etched hard mask layer or a polymer-based etch mask.

11. The method of claim 1, wherein each of the one or more cavities has a salient profile.

12. A method for fabricating photonic devices, the method comprising:
forming a mask layer on a surface of a mold layer, the mask layer defining one or more openings, wherein the one or more openings expose one or more select portions of the surface of the mold layer;
etching through the one or more openings to form one or more cavities within the mold layer;
performing an oxidizing operation on the mold layer to form a first cladding layer;
depositing photonic material within the one or more cavities; wherein depositing the photonic material comprises overfilling the one or more cavities to form an over-filled layer on the mask layer; and
removing the over-filled layer.

13. The method of claim 12, further comprising:
polishing the mold layer before forming the mask layer.

14. The method of claim 12, wherein depositing the photonic material comprises performing atomic layer deposition to fill the one or more cavities with the photonic material.

15. The method of claim 12, wherein depositing the photonic material comprises performing chemical vapor deposition to fill the one or more cavities with the photonic material.

16. The method of claim 12, further comprising:
removing the mask layer.

17. The method of claim 12, further comprising:
depositing a top cladding layer on the first cladding layer.

18. The method of claim 11, wherein forming the mask layer on the mold layer comprises:
forming a patterned resist layer on the mold layer, the patterned resist layer comprising one or more resist structures positioned on the one or more select portions of the surface of the mold layer;
depositing a hard mask layer on the mold layer; and
removing the one or more resist structures to define the one or more openings.

19. The method of claim 18, wherein the one or more resist structures comprises a plurality of resist structures that are spaced apart and distributed across the mold layer, and wherein the hard mask layer has a thickness that is less than the thickness of each of the one or more resist structures.

20. The method of claim 1, wherein each of the one or more cavities has a salient profile.
